(19) United States
(12) Patent Application Publication
(10) Pub. No.: US 2011/0206379 A1
(43) Pub. Date: Aug. 25, 2011

(54) OPTO-ELECTRONIC MODULE WITH IMPROVED LOW POWER, HIGH SPEED ELECTRICAL SIGNAL INTEGRITY

(75) Inventors: Russell A. Budd, North Salem, NY (US); Warren D. Dyckman, Peekskill, NY (US); Gary Lafontant, Elmont, NY (US); Frank R. Libsch, White Plains, NY (US)

(73) Assignee: INTERNATIONAL BUSINESS MACHINES CORPORATION, Armonk, NY (US)

(21) Appl. No.: 12/712,939

(22) Filed: Feb. 25, 2010

(51) Int. Cl. H04B 10/00; H01L 27/14; G06F 17/50; H05K 1/18

(52) U.S. Cl. 398/116; 250/208.2; 361/748; 716/122

(57) ABSTRACT

An apparatus and method for receiving electrical signals and transmitting optical signals includes a substrate having an electrical circuit. An electrical-to-optical module is mounted on the substrate, and the module includes an array of photodetectors communicating with the electrical circuit. The photodetectors may include VCSEL arrays or PD arrays. The module receives electrical signals from the electrical circuit and provides a plurality of corresponding light signals. An electrical transport is embedded in the substrate, and the electrical transport electrically communicates with the array of photodetectors. An optical interface provides electrical communication between an optical fiber and the electrical circuit. A heat transfer device may be positioned adjacent the photodetectors to transfer heat generated by the photodetectors.

### FIELD OF THE INVENTION

The present invention generally relates to an apparatus and method for manufacturing the same in the field of semiconductor technology which provides a removable opto-electronic module and more particularly, relates to an apparatus and method in the field of integrated circuits and chip technology which provides a removable opto-electronic module.

### BACKGROUND

In the field of semiconductor technology, one known typical device using opto-electronic modules includes a multi-channel high-density optical transmitter and receiver pair. The device reduces a fiber count by using coarse wavelength division multiplexing (CWDM). Vertical cavity surface emitting laser (VCSEL) arrays (O/E array) are used in the device and are flip-chip-attached to integrated circuits (ICs). After attachment of the O/E array to the IC, an optical coupling is added. The resulting device is compact. However, the higher electrical density results in difficulty packaging the device with an electrical connector to contact an electrical flex. The device thus uses a direct ball grid array (BGA) solder attach. However, the combination of the electrical flex with the BGA contacts results in a disadvantage of a lower electrical sign-to-noise ratio, as well as, undesirable higher crosstalk. Further, another disadvantage of the exemplary device is that by using a four-wavelength CWDM design to reduce the fiber count, the device requires an optical multiplexer (MUX) and demultiplexer (DEMUX). Another disadvantage of the device is loss associated with the wavelength MUX resulting in a substantial loss of optical power that must be overcome by higher laser powers or increased receiver sensitivity. A still further disadvantage is that the device lacks field replaceability and/or field replaceability of modules which are part of the device.

Therefore, there is a need for an interchangeable (field replaceable) opto-electronic package for optical coupling a multiple channel fiber optic cable(s) to a multiple channel Vertical Cavity Surface Emitting Laser (VCSEL) transmitter array. Further, it would be desirable to provide an interchangeable electronic package for coupling a multiple channel fiber optic cable(s) to a multiple channel photo detector receiver array. Additionally, there is a need for a high speed electrical coupling between an integrated electrical IC chip through the electronic package described above. There is a further need to provide an integrated electrical IC chip improving a signal-to-noise ratio, increasing bandwidth, lowering power consumption, and more specifically, providing improved signal channel isolation and decreasing channel crosstalk. There is also a need to reduce signal channel impedance mismatch, and equalize signal channel skew. Thus, there is a need for a low cost optoelectronic package with low optical loss and low power, improved electrical signal-to-noise ratio, higher bandwidth density package footprint, and having replaceable field flexibility.

### BRIEF SUMMARY OF THE INVENTION

In an aspect of the invention, an apparatus for receiving electrical signals and transmitting of optical signals includes a substrate including an electrical circuit. At least one electrical-to-optical module is mounted on the substrate. The module includes an array of photodetectors communicating with the electrical circuit. The module receives electrical signals from the electrical circuit and provides a plurality of corresponding light signals. An electrical transport is embedded in the substrate, the electrical transport electrically communicates with the array of photodetectors. An optical interface provides electrical communication between an optical fiber and the electrical circuit.

In related aspects, the photodetectors include photodiodes, and the photodiodes include electrical to optical alignment features. Further, the apparatus may include a plurality of electrical to optical modules, wherein at least one module provides electrical to optical communication, and at least one module provides optical to electrical communication. The optical interface may include a self-aligning diode-to-optical adaptor positioning device being part of the optical interface. The apparatus may further include a heat transfer device adjacent to the array of photodetectors for transferring heat from the array of photodetectors. The apparatus may further include a transimpedance amplifier (TIA) in the optical module, the TIA providing a signal-to-noise ratio and an electrical drive level for the electrical circuit. The substrate may include ceramic. The electrical transport may include controlled impedance vias. The apparatus may further include a removable printed circuit or wiring board electrically connected to the substrate, the removable board including an electrically and thermally capable socket connection including land grid array (LGA) or pin grid array (PGA).

In another aspect of the invention, a method for receiving electrical signals and transmitting optical signals, comprises: providing a substrate including an electrical circuit, and providing at least one electrical-to-optical module mounted on the substrate; communicating with the electrical circuit using an array of photodetectors mounted on the module; receiving electrical signals from the electrical circuit on the module and providing a plurality of corresponding light signals; communicating with the array of photodetectors using an electrical transport embedded in the substrate; and communicating between an optical fiber and the electrical circuit using an optical interface.

In another aspect of the invention, a method of controlling impedance, comprises: providing parameters for a substrate having at least one signal via placed parallel to at least one reference via; calculating an average impedance for the signal via and the reference via; and iteratively adjusting the pitch of the signal and reference vias, and the size of the signal and reference vias corresponding to a surrounding dielectric environment until the average impedance of the signal and reference vias are approximately equal to a specified average impedance.

In another aspect of the invention, an apparatus which controls impedance, comprises: a plurality of electrical components positioned on a top layer surface of a substrate; a circuit in the substrate; a thermal escape mechanism adjacent to, and connected to, the electrical components; and an electrical signal escape mechanism communicating with the substrate, the electrical signal escape mechanism having an electrically conductive signal line interconnecting the substrate for an electrical signal to move to and from the substrate.

### BRIEF DESCRIPTION OF THE SEVERAL VIEWS OF THE DRAWINGS

These and other objects, features and advantages of the present invention will become apparent from the following detailed description of illustrative embodiments thereof, which is to be read in connection with the accompanying drawings. The various features of the drawings are not to scale as the illustrations are for clarity in facilitating one skilled in the art in understanding the invention in conjunction with the detailed description. In the drawings:

FIG. 1 is a cross sectional side elevational view of an opto-electronic package including an opto-electronic module and board according to the present invention;

FIG. 2a is a cross-sectional side elevational view of the opto-electronic module shown in FIG. 1 having a waveguide coupling to a photodetector embodied as a VCSEL/PD (vertical-cavity surface emitting laser/photo diode) and waveguide to fiber coupling according to one embodiment of the invention;

FIG. 2b is a detail view of a portion of the opto-electronic module shown in FIG. 2a showing the VCSEL or PD and waveguide to fiber coupling according to one embodiment of the invention;

FIG. 3 is a cross-sectional side elevational view of an opto-electronic package according to another embodiment of the invention including an opto-electronic module with a waveguide coupling to the VCSEL or PD and waveguide to fiber coupling, the package further includes a compliant interconnect of land grid array (LGA);

FIG. 4 is a cross-sectional side elevational view of another embodiment of an opto-electronic package including an opto-electronic module with fiber coupling to the VCSEL or PD;

FIG. 5 is a cross-sectional side elevational view of another embodiment of an opto-electronic package including an opto-electronic module with a fiber coupling to an edge emitter;

FIG. 6 is an isometric view illustrating a semi-transparent layer of a two net electrical interconnect in a package between an electrical support chip and an opto-electronic module showing a high speed electrical transport in an embodiment of the invention;

FIG. 7a is a cross-sectional view along line A-A of the opto-electronic package shown in FIG. 6 including a two net electrical channel layout for passive means of accomplishing equalized net redistribution at an electrical support chip;

FIG. 7b is a cross sectional view along line B-B of the opto-electronic package shown in FIG. 7a;

FIG. 8a is a plan view of an electronic package two net electrical channel layout for passively accomplishing equalized net redistribution at the opto-electronic module according to another embodiment of the invention;

FIG. 8b is a cross sectional view along line C-C of the package shown in FIG. 8a;

FIG. 9 is a cross sectional side elevational detail view of the high speed electrical transport between the silicon chip and the E/O or O/E module shown in FIGS. 2a, and 3-4; and FIG. 10 is a block diagram schematic view of an opto-electronic apparatus according to the invention including a heat transfer device, a chip, and O/E and E/O modules.

### DETAILED DESCRIPTION

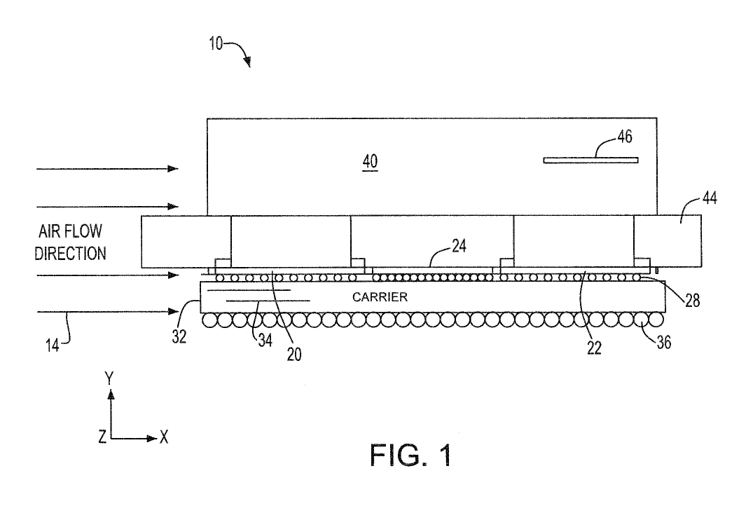

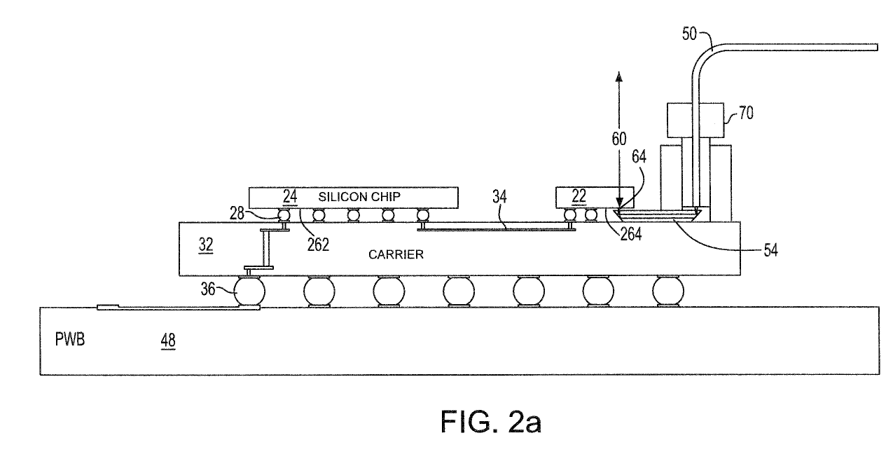

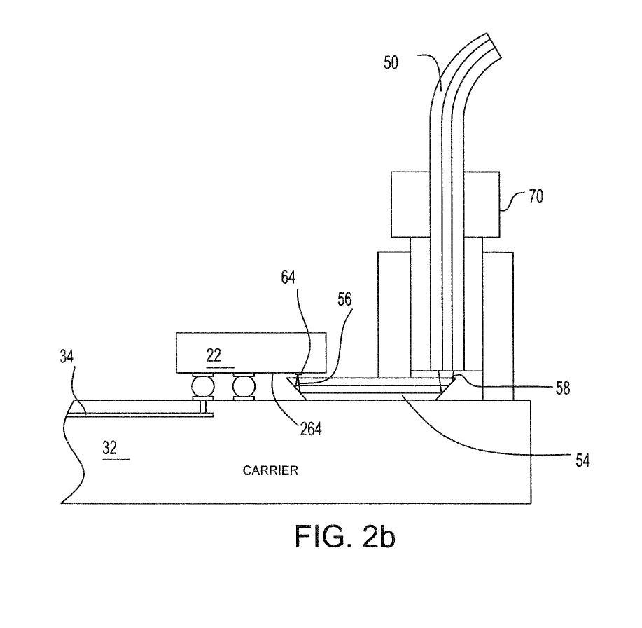

Referring to FIG. 1, in an illustrative embodiment of the present invention, a system and a method for fabrication thereof of an integrated opto-electronic (OE) package or apparatus 10 which includes one or more O/E (optical-to-electrical) modules, and/or one or more E/O modules (electrical-to-optical) 20, 22, respectively. The package 10 further includes one or more electrical chips embodied as a silicon chip 24, and an optical interface to the O/E and E/O modules 20, 22. Electrically conductive elements, in the present embodiment of the invention, C4 ball grid array (BGA) 28, is attached to the O/E and E/O modules 20, 22 and silicon chip 24, and oppositely attached to a substrate embodied as a carrier 32. The substrate may be of a material such as high performance glass ceramic, white alumina ceramic, HI-CTE (high coefficient of thermal expansion) ceramic or Flip Chip-Plastic Ball Grid Array (FC-PBGA). Also, the substrate may be comprised of multiple layers where each layer has a different thickness dimension. The carrier 32 is also connected on an opposite side to another BGA 36, or land grid array (LGA) or other electrical attach means (pin grid array (PGA)) for attachment to, for example, a printed circuit board (PCB) or printed wiring board 48 (PWB) (as shown in FIG. 2a). The printed circuit or wiring board is removable for ease of replacement. The removable board may include an electrically and thermally capable socket connection, which may include, for example, a land grid array (LGA) or pin grid array (PGA).

High speed electrical transport layers 34 are illustratively shown in FIG. 1, in horizontal layers in the carrier 32. A thermal solution for heat transfer is a heat transfer device embodied as a heat sink 40 positioned over integrated stiffeners 44 to provide the appropriate integrated mechanical dimensions for achieving a robust package. Integrated stiffeners 44 include a chemical dielectric product for strengthening the chip alignment and package carrier together. Integrated stiffeners 44 can also be used between the heat conductor product and a chip. In one instance, the heat sink 40 may include a conducting membrane 46. The conducting membrane 46 may be a foil, slug, via, elastomer, epoxy, or BGA balls.

In general, an optical interface in the package 10 is accomplished using an optical path provided by fibers, or an optical flex such as waveguides that collects light from the O/E and E/O modules 20, 22 by various techniques, including: butt coupling, one or more lens relays, light turning elements, or other coupling and light turning elements. Air flow 14 passes the carrier 402 as shown in FIGS. 1 and 10.

Referring to FIG. 2a, a detailed view of the opto-electronic package 10 shown in FIG. 1 includes the carrier 32 between ball grid arrays 28, 36, and the carrier 32 connected to the silicon chip 24 and one E/O module 22 on one side of the carrier 32, and the carrier 32 connected to a PWB 48 on the other side of the carrier 32. The high speed electrical transport 34 connects the chip 24 to the E/O module 22.

An embodiment of an optical interface in accordance with the present invention includes an optical path as provided by fibers 50 coupled to an optical flex such as a waveguide 54 that collects light from the E/O module 22. The waveguide is an embodiment of an optical interface which may include a light transporting channel. The optical interface may include, for example, a mount fiber (MT) mounted fiber cable connector, a waveguide connector, or any other light transporting channel. A self-aligning diode-to-optical adaptor positioning device may comprise fiducial patterns, alignment pins, or solder reflow geometries for positioning the diode array with the optical adaptor. Further, in the embodiment shown in FIG. 2a, the E/O module 22 includes photodetectors embodied as light producing diode arrays, such as a vertical-cavity surface-emitting laser (VCSEL), or in the case of the O/E module 20, the O/E module 20 includes light detecting photo diode (PD) arrays, collectively referred to with reference numeral 64.

Examples of VCSELs and PDs in opto-electronic packages are depicted in co-pending and commonly owned U.S. patent application Ser. Nos. 12/544,710 and 12/544,696, the disclosures of which are expressly incorporated by reference herein in their entirety.

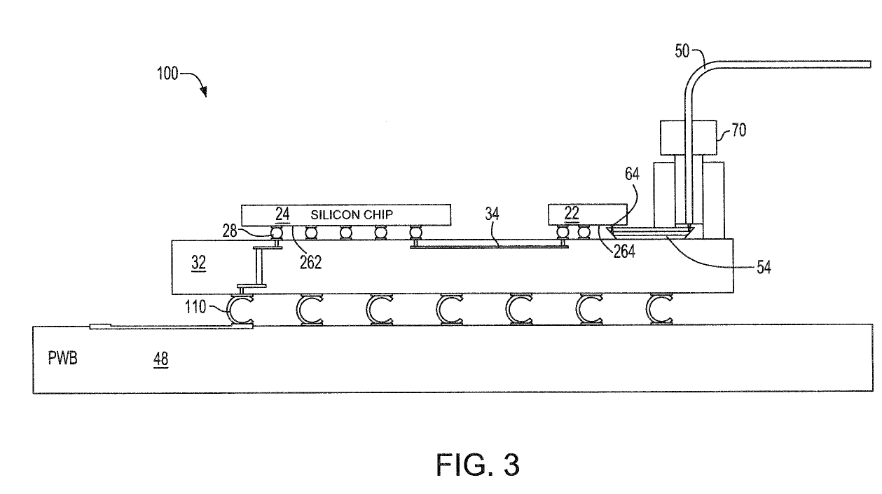

In general, the O/E and E/O modules 20, 22 may contain additional electrical support chips. In the embodiment of the invention shown in FIG. 2a, light 60 exiting the E/O 22 or entering the O/E 20 to the diodes is traveling in the vertical direction. The waveguide 54 contains a turning mirror 56 (shown in FIG. 3b) for turning the light from a horizontal direction to a vertical direction or vice versa. A second turning mirror 58 (shown in FIG. 2b) at the other end of the waveguide 54 provides an interface with the optical fiber 50. The optical fiber 50 is perpendicular to the waveguide 54 and includes a vertical light core.

Turning mirrors can be fabricated by having a highly smooth, surface, for example, at a tolerance close to a 45 degree angle to the incoming light direction, and relying on an optical index step difference in the waveguide channel core to the other side of the 45 degree bevel, such as an air cavity, or relying on an optical reflective surface, such as can be accomplished with thin film metal depositions. In the embodiment of the invention shown in FIG. 3a, the E/O module 22 includes an array of VCSEL diode light sources, while the O/E module 20 contains an array of photodetector light diodes with a transimpedance amplifier (TIA) 405 to improve the electrical signal to noise ratio. There may be other control electrical circuitry, but for cost and packaging density improvement, the E/O module 22 electrical support circuitry chip(s), such as a driver chip, can be eliminated since the driver circuitry is consolidated into the existing silicon chip 24. This merging and consolidation is made possible by the high speed electrical transport 34 in the carrier 32 between the silicon chip 24 and the E/O module 22 ensuring a good signal to noise ratio. The high speed electrical transport 34 is impedance controlled and skew matched. The consolidating of the driver circuitry with the controlled and matched high speed electrical support in the carrier provides for lower power dissipation. In addition, a plurality of silicon chips may be used which contain additional circuitry that improves performance of the E/O 22 or O/E 20 array, such as a microcontroller or other circuitry for automatic power and temperature control. The E/O or O/E module 22, 20, as well as the silicon chip(s) 24 may be bumped by attaching C4 balls 28, and using standard flip chip bonding tools to complete the assembly to the carrier 32. The E/O or O/E module 22, 20 with other silicon chip(s) may also use other interconnect elements such as pins, columns, thermal compression, to attach to the carrier 32.

The waveguide 54 may be fabricated from polymer material directly on the carrier 32, or transferred from a waveguide on a flex substrate onto the carrier. Various polymer waveguide thin film deposition techniques are available, such as doctor blading, spin coating, inkjet deposition, slot coating, etc., and other waveguide patterning techniques, such as UV crosslinking via photolithography or direct laser writing, molding, embossing, etc. The optical connector-to-carrier interface, BGA 28 to carrier 32, may be aligned to the waveguide core, to fiducials, or other visual patterns with mechanical dimensions, such as with mechanical alignment pins, with mating recessed cavities or raised geometries, such as solder reflow geometries for positioning the diode array with the optical adaptor.

In the final placement of the electro-optical package 10, including the carrier 32 with all attached chips, for example the chip 24, and the optical connector embodied as the waveguide 54, is attached to the PWB 48 by BGA 36 or other electrical contacts. The carrier 32 can be made of various materials such as ceramic substrate: high performance glass ceramic (HPGC) and White Alumina Ceramic, or organic substrate (flip-chip plastic ball grid array (FC-PBGA). An optical ferrule 70 is attached after the PWB 48 and the heat sink 40 (shown in FIG. 1).

Referring to FIG. 2b, a detail view of the VCSEL/PD area of the package 10 shown in FIG. 2a includes the VCSEL or PD 64 and waveguide 54 to fiber coupling according to one embodiment of the invention. To achieve minimum optical signal low with low power operation, of importance is the optical alignment between the VCSEL/PD 64 to the waveguide 54 alignment and the waveguide 54 to optical fiber 50 alignment. Economical assembly costs are achieved using passive alignment between the VCSEL/PD 64 and the waveguide 54, and the waveguide 54 to the optical fiber 50. The alignment may be accomplished by visual patterns and/or mechanical interlocking dimensions on the three components above. In addition to the three components, the carrier 32 may contain visual alignment patterns and/or mechanical dimensions that may provide reference for each of the three components. The alignment patterns and/or mechanical dimensions may be formed during other fabrication steps to reduce costs of their fabrication. For example, carrier alignment fiducials may be formed during the same fabrication step of forming the BGA pads, and from the same metal material.

Referring to FIG. 3, another embodiment according to the invention of an opto-electrical package 100 includes elements as in the embodiment of FIG. 2a with the same reference numerals. However, in the package 100 the flexibility of incorporating other carrier-to-PWB 48 electrical connection is embodied as a land grid array (LGA) 110. Further, the final placement of the electro-optical package 100, including the carrier 32 with attached chips 24 and the optical connector embodied as the waveguide 54, is attached to the PWB 48 by a compliant interconnect of the LGA 110 contacts. One advantage of the LGA 110 is field replacability of the carrier 32 and thereby all components on the carrier 32 is easier using the LGA 110. The LGA does not have to be soldered into place and thus can be plugged and unplugged at will, with less technical effort than a soldered or otherwise attached component.

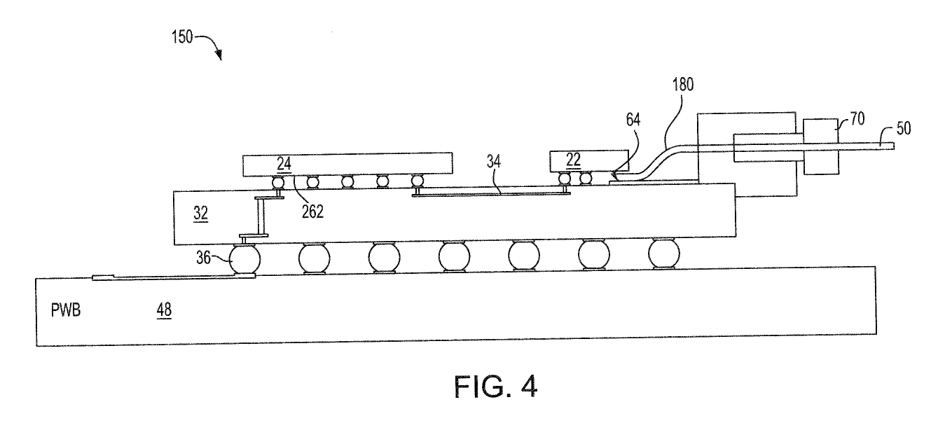

Referring to FIG. 4, another embodiment of an opto-electronic package 150 according to the invention is shown, wherein like elements have the same reference numerals as in previous embodiments. The opto-electronic package 150 includes a module 160 with a fiber coupling 170 to the VCSEL/PD 64. An optical path exits/enters the VCSEL/PD 64 vertically with a 45 degree faucet, turning the optical path horizontally into/out of the optical fiber 50. The optical ferrule 70, for example, mates any external optical fibers to the fiber jumper 180 on the carrier 32.

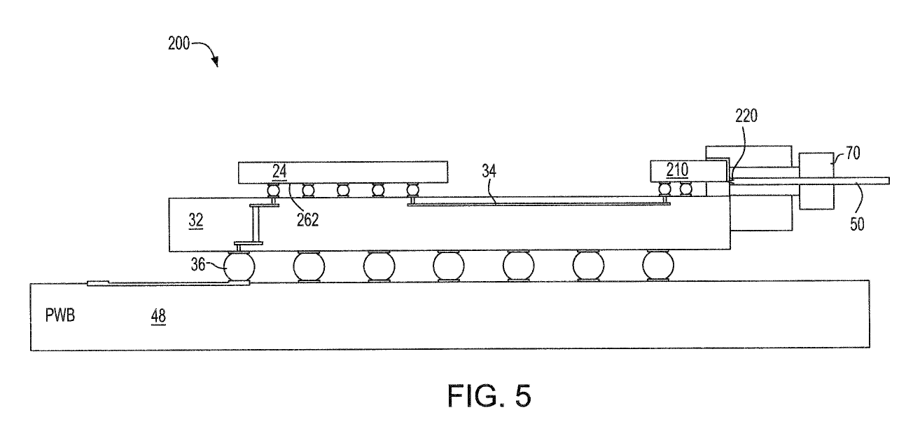

Referring to FIG. 5, another embodiment of an opto-electronic package 200 according to the invention is shown, wherein like elements have the same reference numerals as in previous embodiments. An optical path in the package 200 exits an edge emitter 210 horizontally into the fiber 50, thus eliminating the need for turning the optical path for the horizontal optical fiber ferrule 70. It is understood that turning of the optical path may include turning the optical path upwards away from the carrier 32, downwards towards the carrier 32, horizontally, or at any angle between horizontal and vertical axes.

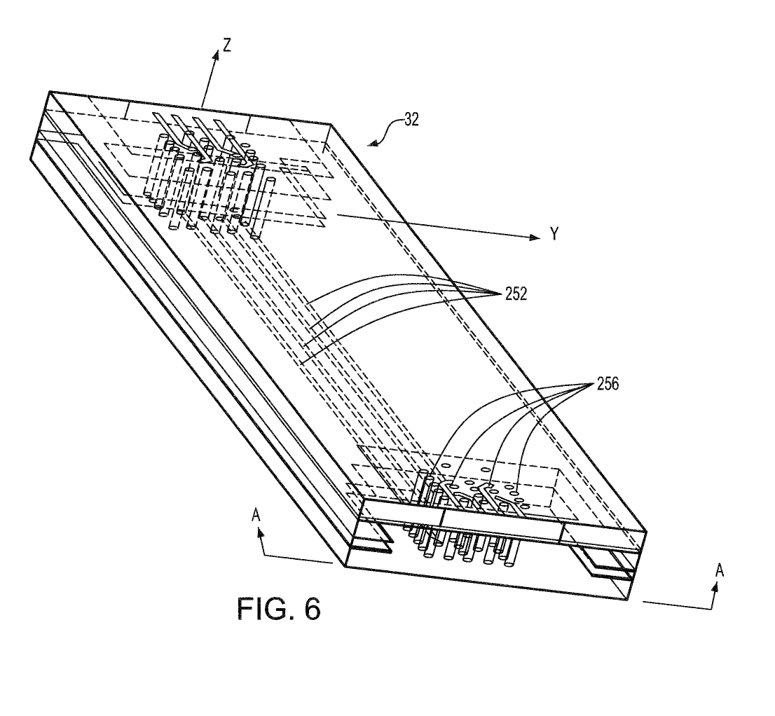

Referring to FIG. 6, an embodiment of the carrier shown in FIGS. 2a, 2b, and 3-5 includes integrated high speed electrical interconnects between an electrical chip side 262 of the silicon chip 24 (shown in FIGS. 1-5) and the optical module side 264 of the OE module 22 (shown in FIGS. 1-3). In the carrier 32, high speed signals need constant impedance value along their traveling path to minimize return loss or reflection. In carrier packaging, the routing path of a net (a signal line trace) consists of C4, BGA ball, pad, line etch and via. Line etches 252, are the longest part of the net, and has its impedance controlled through line width, line-to-line spacing and dielectric thickness in a stripline or microstrip structure. Via structures 256, are usually much shorter than line etches 252, but their impedance electrical characteristic can be important in high speed applications where electrical wavelengths are shorter at higher order of speed.

The difference in time of flight between a differential signal pair nets is referred to herein as skew. In the present invention, the high speed transport created by a signal trace on top of the packages including CIV allows flexibility to reduce the skew. The CIV structures allow impedance control with trace stripline or microstrip structures routed on the upper layers of package. Minimizing impedance variation between different structures is beneficial to the signal integrity of the line.

Therefore, in order to control and maintain impedance matching along a signal net path, via impedance matching techniques (CIV) are applied. CIV uses via diameter size, via to via spacing, as well as multiple via patterning to control and match impedance with a signal line structure. For example, the carrier 32 shown in FIG. 6, includes a footprint with 200 μm pitch using 80 μm via, and where a method and pattern have been applied to maintain via impedance in a white alumina ceramic package to (+/−10%) 50 ohms characteristic impedance and (+/−15%) 100 ohms differential impedance. The pattern of FIG. 6 is the following:

In the above pattern, the high signal select (HSS) signal via is represented by the S. The numbered positions are on a 200 μm pitch from the HSS via. The lettered positions are on a 400 μum pitch from the HSS via.

The CIV method above follows the following rules: there must be ground (GND) vias in the 1 and 4, or 2 and 3 positions; no other vias are allowed on a 200 μm pitch from the HSS via; HSS differential pair vias must be a minimum of 600 μm pitch from each other; any type of vias, except differential pair vias above, are allowed on the lettered pitch under these conditions; and no more than 4 vias are allowed in the A,C,F and H positions, or no more than 2 vias are allowed in the B, D, E and G positions.

For minimum layout area constraint cases, the following rule relaxations may be considered, albeit at a less than optimum signal-to-noise ratio and/or increased power: three or four vias may be used in the B, D, G, and E positions; no other vias are allowed within 400 μm of the signal via; and at lease two ground vias should be at opposite positions (vertical, horizontal) to the signal via, the others can be power vias in case ground bias are not possible.

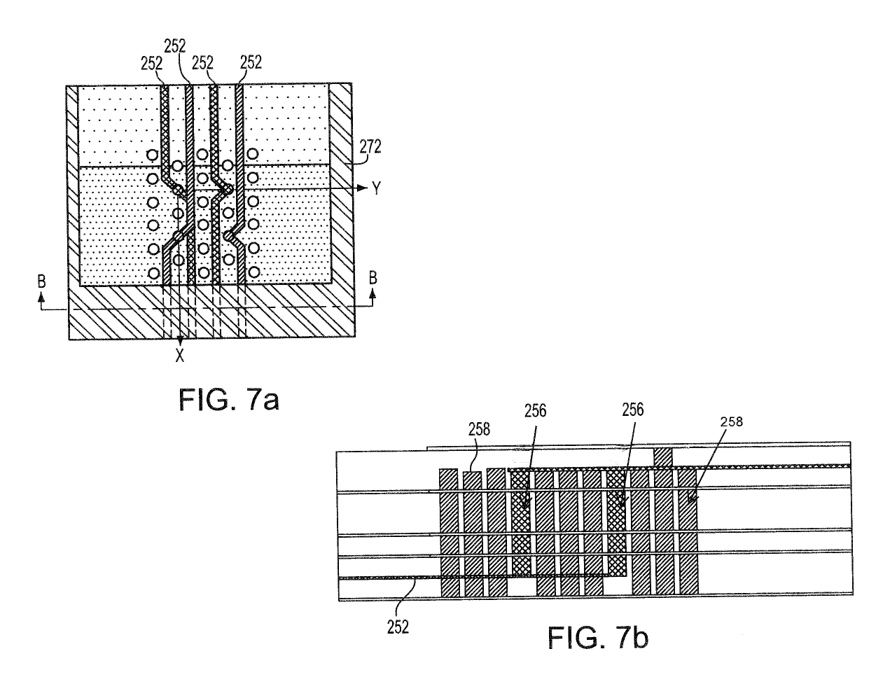

Using the above methodology, FIGS. 7a and 7b show the top side 272 metallurgy of the carrier 32 shown in FIG. 6, is shown having line etches 252 (cross-section slice at X=0 plane, at A-A shown in FIG. 6) for implementing four HSS signal vias for the carrier 32 shown in FIG. 6, showing the electrical chip side 262 of the silicon chip. The vias 256 are adjacent reference vias 258 as shown in FIG. 7b. The top side 272 depicts an embodiment of an equalized net redistribution for conveying electrical signals.

In alternative embodiments, a plurality of via patterns may relate to a plurality of signal vias, reference vias, pitch dimensions, substrate dielectric materials, and via sizes.

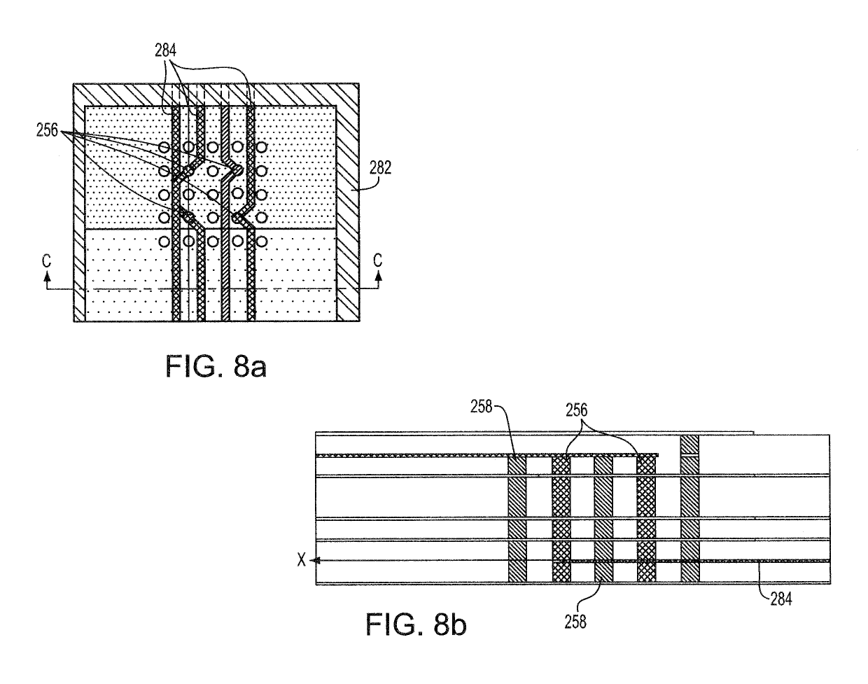

Referring to FIGS. 8a and 8b, another embodiment of a top side 282 metallurgy (cross-section slice with X being constant and >0) of the carrier 32 shown in FIG. 6, is shown implementing four HSS signal vias for the corresponding carrier location at the optical module side 264 of the OE module 22, and includes line etches 284. Signal vias 256 are adjacent reference vias 258 as shown in FIG. 8b. The top side 282 depicts another embodiment of an equalized net redistribution for conveying electrical signals.

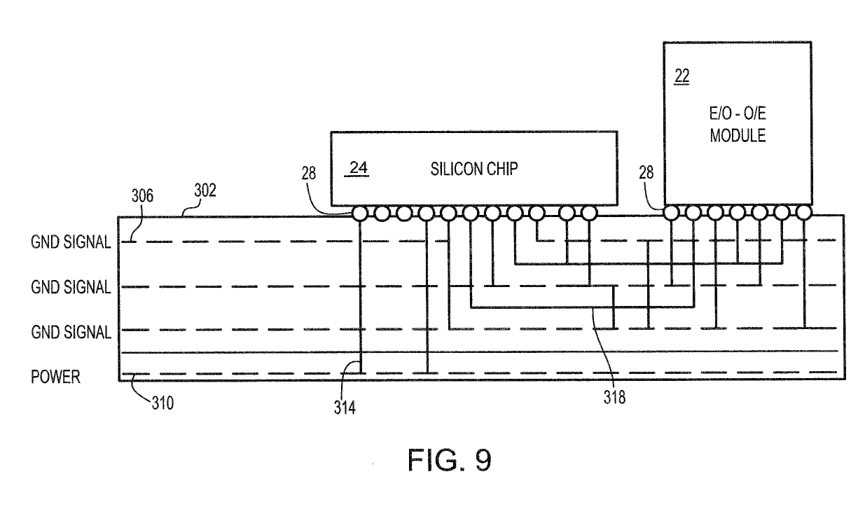

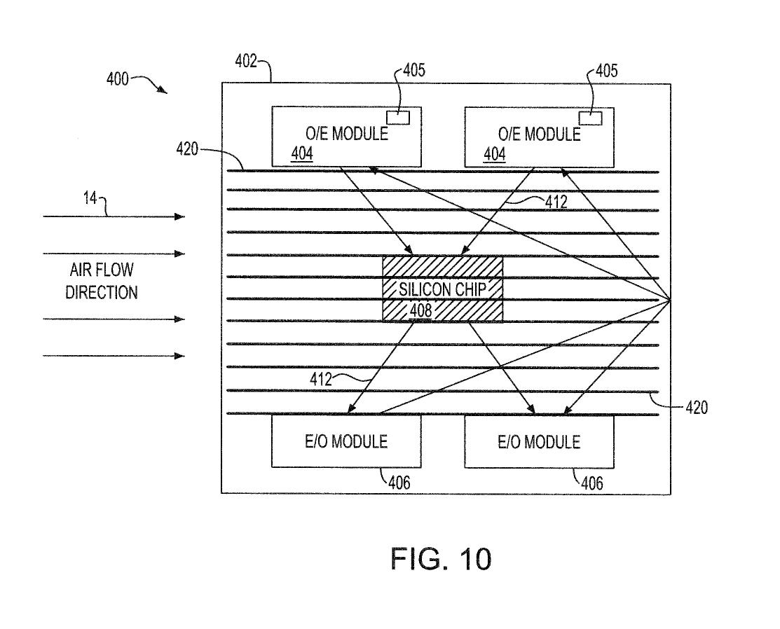

Referring to FIG. 9, a carrier 302 includes the silicon chip 24 and the E/O-O/E module 22 mounted on the carrier 302. The carrier 302 further includes ground signal lines 306 and signal power lines 310. A plurality of vias 314 are connected to the BGAs 28 between the chip 24 and the carrier 302, and between the module 22 and the carrier 302. The vias 314 also connect to conductive lines 318.

Referring to FIG. 10, an integrated opto-electronic package 400 includes O/E modules 404 and E/O modules 406 on a carrier 402. A silicon chip 408 is positioned central to the O/E and E/O modules 404, 406, respectively. Four arrows 412 show schematically the high speed electrical transport layers locations in the carrier 412 going from the silicon chip 408 to the E/O modules 406 or from the O/E modules 404 to the silicon chip 408. Air flow 14 passes the carrier 402 as shown in FIG. 10. Heat transfer devices 420 are included in the package 400.

Thereby, the embodiments of the present invention discussed above provide a package for coupling multiple parallel channel fiber optic cable to a multiple parallel channel VCSEL transmitter. The packages further provide coupling the same or a second multiple parallel channel fiber cable to a multiple parallel channel PD receiver with a packaging solution that gives both high electrical signal integrity at a high bandwidth density, as well as, field replaceability. The invention provides an interchangeable (field replaceable) package for optical coupling a multiple channel fiber optic cable(s) to a multiple channel Vertical Cavity Surface Emitting Laser (VCSEL) transmitter array, or a multiple channel Photo Diode (PD) receiver array, or both. The invention further provides high speed electrical coupling between the on package integrated electrical IC chip through the package. The integrated electrical IC chip may encompass functions that improve, in general, signal-to-noise and increase bandwidth, lower power consumption, and specifically, provide improved signal channel isolation and decrease channel crosstalk, reduce signal channel impedance mismatch, and equalize signal channel skew. These functions may include circuits that are electrical drivers, equalization, voltage level shifters, and multiplexers. The electrical IC chip may also have additional functions other than the sole support of the VCSEL or PD signal integrity. The additional circuit functions may include, for example, processors, memory, and switching networks. These additional functions may advantageously benefit from having the electrical-to-optical and optical-to-electrical modules in close proximity, as it may increase bandwidth, bandwidth density, signal-to-noise, latency, cost, lower power consumption, etc.

While the present invention has been particularly shown and described with respect to preferred embodiments thereof, it will be understood by those skilled in the art that changes in forms and details may be made without departing from the spirit and scope of the present application. It is therefore intended that the present invention not be limited to the exact forms and details described and illustrated herein, but falls within the scope of the appended claims.

What is claimed is:

1. An apparatus for receiving electrical signals and transmitting of optical signals, comprising:
a substrate including an electrical circuit;
at least one electrical-to-optical module mounted on the substrate, the module including an array of photodetectors communicating with the electrical circuit, the module receives electrical signals from the electrical circuit and provides a plurality of corresponding light signals;
an electrical transport embedded in the substrate, the electrical transport electrically communicating with the array of photodetectors; and
an optical interface providing electrical communication between an optical fiber and the electrical circuit.

2. The apparatus of claim 1, wherein the photodetectors include photodiodes.

3. The apparatus of claim 2, wherein the photo diodes include electrical to optical alignment features.

4. The apparatus of claim 1, further comprising a plurality of electrical to optical modules, wherein at least one module provides electrical to optical communication, and at least one module provides optical to electrical communication.

5. The apparatus of claim 1, wherein the optical interface includes a self-aligning diode-to-optical adaptor positioning device being part of the optical interface.

6. The apparatus of claim 1, further comprising:
a heat transfer device adjacent to the array of photodetectors for transferring heat from the array of photodetectors.

7. The apparatus of claim 1, further including a transimpedance amplifier (TIA) in the optical module, the TIA providing a signal-to-noise ratio and an electrical drive level for the electrical circuit.

8. The apparatus of claim 1, wherein the substrate includes ceramic.

9. The apparatus of claim 1, wherein the electrical transport includes controlled impedance vias.

10. The apparatus of claim 1, further including:
a removable printed circuit or wiring board electrically connected to the substrate, the removable board including an electrically and thermally capable socket connection including land grid array (LGA) or pin grid array (PGA).

11. The apparatus of claim 6, wherein the heat transfer device includes a conducting membrane.

12. A method for receiving electrical signals and transmitting optical signals, comprising:
providing a substrate including an electrical circuit, and providing at least one electrical-to-optical module mounted on the substrate;
communicating with the electrical circuit using an array of photodetectors mounted on the module;
receiving electrical signals from the electrical circuit on the module and providing a plurality of corresponding light signals;
communicating with the array of photodetectors using an electrical transport embedded in the substrate; and
communicating between an optical fiber and the electrical circuit using an optical interface.

13. The method of claim 12, further comprising:
aligning the optical interface with the photodetectors using optical alignment features on the photo detectors.

14. The method of claim 12, further comprising:
communicating between the electrical circuit and the optical interface.

15. The method of claim 12, further comprising:
communicating and converting electrical signals to optical signal using at least one module; and
communicating and converting optical signals to electrical signals using at least one another module.

16. The method of claim 12, further comprising:
automatically aligning the photodetctors with the optical interface.

17. The method of claim 12, further comprising:
transferring heat from the array of photodetectors using a heat transfer device.

18. The method of claim 12, further comprising:
receiving a plurality of electrical signals;
conveying the electrical signals using an equalized net redistribution into a precision matched electrical skew;
receiving a plurality of electrically matched skew signals from the net redistribution; and
converting the plurality of electrically matched skew signals into a plurality of corresponding optical signals.

19. A method of controlling impedance, comprising:
providing parameters for a substrate having at least one signal via placed parallel to at least one reference via;
calculating an average impedance for the signal via and the reference via; and
iteratively adjusting the pitch of the signal and reference vias, and the size of the signal and reference vias corresponding to a surrounding dielectric environment until the average impedance of the signal and reference vias are approximately equal to a specified average impedance.

20. The method of claim 19, wherein the substrate includes multiple layers and each layer has a different dimension thickness.

21. An apparatus which controls impedance, comprising:
a plurality of electrical components positioned on a top layer surface of a substrate;
a circuit in the substrate;
a thermal escape mechanism adjacent to, and connected to, the electrical components; and
an electrical signal escape mechanism communicating with the substrate, the electrical signal escape mechanism having an electrically conductive signal line interconnecting the substrate for an electrical signal to move to and from the substrate.

22. The apparatus of claim 21, wherein the electrical signal escape mechanism is a high speed electrical transport being part of the circuit in the substrate, and the high speed electrical transport interconnects the electrical components positioned on the top layer surface of the substrate.

23. The apparatus of claim 21, wherein the circuit in the substrate contains control impedance vias (CIVs).

24. The apparatus of claim 21, wherein the circuit in the substrate contains equalized signal skew channels using the CIVs and wiring in the top layer.

25. The apparatus of claim 21, wherein the substrate is a material from the group comprising: high performance glass ceramic, white alumina ceramic, organic packaging and printed wiring board.
